(19) United States
(12) Patent Application Publication
(10) Pub. No.: US 2012/0268141 A1
(43) Pub. Date: Oct. 25, 2012

(54) METHOD AND ARRANGEMENT FOR MEASURING THE SIGNAL DELAY BETWEEN A TRANSMITTER AND A RECEIVER

(76) Inventors: Roland Gierlich, Ulm (DE); Jörg Hüttner, Munchen (DE); Andreas Ziroff, Passau (DE)

(21) Appl. No.: 13/504,290

(22) PCT Filed: Oct. 25, 2010
(86) PCT No.: PCT/EP2010/066032

§ 371 Date: Jul. 8, 2012

(30) Foreign Application Priority Data
Oct. 27, 2009 (DE) 10 2009 050 796.5

(51) Int. Cl. G01R 27/28

(52) U.S. Cl. 324/617

(57) ABSTRACT

A method for determining a delay τ of a signal between a UWB transmit unit and a FSCW receiver unit includes: generating a pulsed transmit signal Sₜᵣ by the transmit unit and emitting the pulsed transmit signal Sₜᵣ, the transmit signal Sₜᵣ comprising a broadband spectrum SPEKₜᵣ having a plurality of lines w; receiving the emitted signal Sₜᵣ by the receiver unit as a received signal Sᵣₓ, wherein the received signal Sᵣₓ comprises a broadband spectrum SPEKᵣₓ having a plurality of lines m; determining at the receiver unit a channel impulse response hₙ of the received signal Sᵣₓ; and determining the signal delay τ based on the channel impulse response hₙ.

### CROSS-REFERENCE TO RELATED APPLICATIONS

This application is a U.S. National Stage Application of International Application No. PCT/EP2010/066032 filed Oct. 25, 2010, which designates the United States of America, and claims priority to DE Patent Application No. 10 2009 050 796.5 filed Oct. 27, 2009. The contents of which are hereby incorporated by reference in their entirety.

### TECHNICAL FIELD

The disclosure relates to measuring the signal delay between a UWB transmitter and a FSCW receiver.

### BACKGROUND

A precise determination of the position of a radio transmitter and/or the distance of the radio transmitter from a base station or the like is of importance for instance in the industrial field. Aside from the need for cost- and energy-saving measuring systems, particularly for applications in closed rooms or halls, it is necessary in this way, on account of possibly disturbing multipath reflections, to use measuring systems with a high resolution, in order to prevent errors in the distance measurement. For instance UWB signals (“ultra wide band”) offer a high signal band width and therefore promise a comparatively high resolution and higher accuracy.

Different methods are known for the position and/or distance determination, which use optical signals, ultrasound signals or radio sensors for instance. The clear relationship between the distance and the delay of the signal is generally used, i.e., ultimately this involves a delay measurement. The terms “distance measurement” and “delay measurement” can in principle therefore be used below synonymously.

In particular, the method for distance measurement with the aid of radio signals can be divided into three categories:
Communication-based systems: here the signal used primarily for communication purposes is used for distance measurement. Since minimal demands are placed on the synchronization in many communication systems, and/or a very narrow band radio channel is available, no high achievable accuracies in terms of distance measurement are to be expected.
FMCW—FSCW solutions: these systems operate in the ISM bands (“Industrial, Scientific, and Medical) and enable the determination of a distance value in a similar fashion to conventional FMCW radar (frequency modulated continuous wave) by tuning a transmission frequency. On the one hand transponder-based and/or so-called “backscatter” solutions are used here and on the other hand receivers which can be synchronized thereto. In terms of their usage, these systems are restricted to the bands enabled herefor. These are generally the ISM bands, with which a bandwidth of 80 MHz in the 24 GHz band and a bandwidth of 150 MHz in the 5.8 GHz band are available.
UWB systems: these systems use new regulatory instructions, which allow for the transmission of very broadband signals, but which nevertheless have a very minimal energy spectrum. Corresponding UWB systems are known for instance from U.S. Pat. No. 7,418,029 B2, US 2006/033662 A1 or U.S. Pat. No. 6,054,950 A. The receiver architectures may be for instance non-coherent receivers with power detectors, whereby in the event of a pure power detection, the accuracy of the distance measurement deteriorates. On the other hand, coherent receivers can also be used, which nevertheless either require very long correlation times or an extremely high scanning rate. The receiver generally includes a correlator unit, in which the received pulse sequence is correlated with a locally generated sequence. The realization of such a receiver is however comparatively complicated since no commercial IC components are currently available.

### SUMMARY

In one embodiment, a method for determining a delay τ of a signal between a UWB transmit unit and a FSCW receive unit is provided, in which: in a first step a pulsed transmit signal Sₜᵣ is generated by the transmit unit and emitted, wherein the transmit signal Sₜᵣ comprises a broadband spectrum SPEKₜᵣ having a plurality of lines w; in a second step, the emitted signal Sₜᵣ is received by the receive unit, whereby the received signal Sᵣₓ comprises a broadband spectrum SPEKᵣₓ having a plurality of lines m; in a third step in the receive unit a channel impulse response hₙ of the received signal Sᵣₓ is determined; and in a fourth step, the delay τ is determined from the channel impulse response hₙ.

In a further embodiment, after the second step, a partial spectrum TSPEKᵣₓ, which covers a frequency range B having a narrower bandwidth H_{LPR} and having a lesser number of lines m′, is initially selected from the broadband spectrum SPEKᵣₓ of the received signal Sᵣₓ; in the third step, the channel impulse response hₘ, is determined with the aid of the lines m′ of the selected partial spectrums TSPEKᵣₓ; and in the fourth step, the delay τ is determined from this channel impulse response h_{m′}.

In a further embodiment, it takes place in several partial steps k with k=1, 2, 3, . . . , wherein: after the second step, a partial spectrum TSPEKᵣₓ(k), which covers a frequency range B(k) having a narrower bandwidth H_{LPR} and having a lesser number of lines m′, is initially selected from the broadband spectrum SPEKᵣₓ of the received signal Sᵣₓ, wherein in each partial step k, another narrow band partial spectrum TSPEKᵣₓ(k) is selected; in the third step, the channel impulse response h_{m′}(k) is determined with the aid of the lines m′ of the selected partial spectrum TSPEKᵣₓ(k); and in the fourth step, the delay τ is determined from this channel impulse response h_{m′}(k). In a further embodiment, in a partial step k for selecting a partial spectrum TSPEKᵣₓ(k), a reference signal S_{LO}(k), in particular a local oscillator signal, is generated with a frequency f_{LO}(k), wherein: the received signal Sᵣₓ is mixed down with the LO signal S_{LO}(k) in a mixer; and the narrow band frequency range B(k) is selected from the output signal of the mixer which results therefrom. In a further embodiment, the frequency f_{LO}=f_{LO}(k) of the reference signal S_{LO}(k) is gradually changed for the individual partial steps k.

In another embodiment, a distance measuring arrangement for measuring a signal delay τ between a transmit unit and a receive unit is provided, wherein: the transmit unit is embodied as an ultra wideband transmitter, which is suited to transmitting a pulsed transmit signal Sₜᵣ, wherein the transmit signal Sₜᵣ comprises a broadband spectrum SPEKₜᵣ having a plurality of lines w; and the receive unit comprises a FSCW receiver for receiving the transmitted transmit signal Sₜᵣ, wherein the received signal Sᵣₓ includes a broadband spectrum SPEKᵣₓ having a plurality of lines m, and comprises an evaluation unit, which is embodied to determine a channel impulse response hₙ τ from the received signal Sᵣₓ and the signal delay τ from the channel impulse response hₙ.

In a further embodiment, the receive unit also comprises: an adjustable local oscillator for generating a local oscillator signal S_{LO}(k), wherein the signal S_{LO}(k) comprises a frequency f_{LO}(k) which can be adjusted in steps k with k=1, 2, . . . ; and a mixer, to which the received signal Sᵣₓ and the LO signal S_{LO}(k) can be fed and in which these signals are mixed in a base band signal, wherein the output signal of the mixer is used to determine the channel impulse response hₙ and the signal delay τ in the evaluation unit. In a further embodiment, the receive unit also comprises a filter, to which the base band signal is fed, and in which a narrow band partial spectrum TSPEKᵣₓ(k) can be selected from the spectrum of the base band signal, whereby instead of the output signal of the mixer, the output signal of the filter is used to determine the channel impulse response hₙ and the signal delay τ in the evaluation unit.

### BRIEF DESCRIPTION OF THE DRAWINGS

Example embodiments will be explained in more detail below with reference to figures, in which:

FIG. 1 shows an example arrangement for delay measurement, according to one embodiment,

FIGS. 2A and 2B show the transmit signal as a function of time and of frequency,

FIG. 3 shows the temporal development of the phases of different lines of the receive spectrum, and

FIG. 4 shows a cutout from the spectrum of the receive signal, which overlays the individual lines according to the different frequencies of the receiver local oscillator signals.

### DETAILED DESCRIPTION

Some embodiments provide a simple option of determining a distance between a transmitter and a receiver.

For example, some embodiments provide a method for determining a delay τ of a signal between a UWB transmit unit and a FSCW receive unit, which comprises: —in a first step a pulsed transmit signal Sₜᵣ is generated and emitted by the transmit unit, whereby the transmit signal Sₜᵣ comprises a broadband spectrum SPEKₜᵣ having a plurality of lines w,
in a second step the emitted signal Sₜᵣ is received by the receive unit, whereby the received signal S_{rz} comprises a broadband spectrum SPEKₜᵣ having a plurality of lines m,
in a third step a channel impulse response hₙ of the received signal Sᵣₓ is determined in the receive unit, and
in a fourth step the delay τ is determined from the channel impulse response hₙ

In an example embodiment, a partial spectrum TSPEKᵣₓ which covers a frequency range B having a narrower bandwidth H_{LPR} and a having a lesser number of lines m′, is initially selected after the second step from the broadband spectrum SPEKᵣₓ of the received signal Sᵣₓ. In the third step, the channel impulse response h_{m′} is then determined with the aid of the lines m′ of the selected partial spectrum TSPEKᵣₓ. In the fourth step, the delay τ is finally determined from this channel impulse response h_{m′}.

In an alternative embodiment of the method, this takes place in several partial steps k with k=1, 2, 3, . . . , wherein
after the second step, a partial spectrum TSPEKᵣₓ(k) which covers a frequency range B(k) having a narrower bandwidth H_{LPR} and having a lesser number of lines m, is initially selected from the broadband spectrum SPEKᵣₓ of the received signal Sᵣₓ, wherein in each partial step k, a different narrow band partial spectrum TSPEKᵣₓ(k) is selected,
in the third step, the channel impulse response h_{m′}(k) is determined with the aid of the lines m′ of the selected partial spectrum TSPEKᵣₓ(k) and
in the fourth step, the delay τ is determined from this channel impulse response h_{m′}(k).

In some embodiments, a reference signal S_{LO}(k), in particular a local oscillator signal, is generated with a frequency f_{LO}(k) in a partial step k in order to select a partial spectrum TSPEKᵣₓ(k) wherein
the received signal Sᵣₓ is mixed with the LO-Signal S_{LO}(k) in a mixer and
the narrower band frequency range B(k) is selected from the output signal of the mixer resulting therefrom.

The frequency f_{LO}=f_{LO}(k) of the reference signal S_{LO}(k) may in this way be gradually changed for the individual partial steps k.

Some embodiments provide a distance measuring arrangement for measuring a signal delay τ between a transmit unit and a receive unit, wherein the transmit unit to be embodied as an ultra broadband transmitter, which is suited to transmitting a pulsed transmit signal Sₜᵣ, whereby the transmit signal Sₜᵣ comprises a broadband spectrum SPEKₜᵣ having a plurality of lines w, and

wherein the receive unit comprises an FSCW receiver for receiving the transmitted transmit signal Sₜᵣ, whereby the received signal Sᵣₓ includes a broadband spectrum SPEKᵣₓ having a plurality of lines m, and comprises an evaluation unit, which is embodied so as to determine a channel impulse response hₙ from the received signal Sᵣₓ and the signal delay τ from the channel impulse response hₙ.

In some embodiments of the distance measuring arrangement, the receive unit also comprises:
an adjustable local oscillator for generating a local oscillator signal S_{LO}(k), wherein the signal S_{LO}(k) has a frequency f_{LO}(k) which can be adjusted in steps k with k=1, 2, . . . ,
a mixer, to which the received Sᵣₓ and the LO-signal S_{LO}(k) can be fed and in which these signals are mixed in a base band signal,
   whereby the output signal of the mixer is used to determine the channel impulse response hₙ and the signal delay τ in the evaluation unit.

Furthermore, the receive unit may comprise a filter, to which the base band signal is fed and in which a narrow band partial spectrum TSPEKᵣₓ(k) can be selected from the spectrum of the base band signal, whereby instead of the output signal of the mixer, the output signal of the filter is used to determine the channel impulse response hₙ and the signal delay τ in the evaluation unit.

Some embodiments utilize or provide the advantages of a UWB transmitter and those of the FSCW receiver.
Short high frequency pulses are also included in the UWB signals emitted by a UWB transmitter, such as are used in the present disclosure. The use of short HF pulses advantageously enables low-current transmitters to be created. Furthermore, signals of this type are excellently suited to distance measuring systems on account of their high band width and short time period.
According to the US regulatory authority FCC too, only pulsed and not FMCW-modulated signals are permitted to be sent. FSCW signals are generally used in radar technology. On account of the evaluation of these signals in the frequency range throughout a specific time frame, such systems profit from a high processing gain.

Further advantages of certain embodiment include providing a simple UWB transmitter architecture, and an established narrow band receiver structure.

In a simple case, only a coherently oscillating pulse generator is needed on the transmitter side, the repetition frequency of which is predetermined by an oscillator circuit. Contrary to conventional UWB receiver systems, a narrow band intermediate frequency architecture is possible, which is comparable with that of FSCW systems. Contrary to UWB correlation receivers with fixed correlation signals, the processing gain can also be influenced by selection of the measuring duration. Furthermore, this architecture enables the virtually coherent receipt of the UWB signal. This means that the signal to be evaluated is not received all at once but is instead composed coherently. Accordingly, the phase information can also be used for evaluation purposes. As a matter of principle, this is indispensable for the precise determination of the channel impulse response.

The methods ands systems disclosed herein can also be used for positioning and distance measurement in the industrial field, whereby robust solutions and a high resolution are desired.

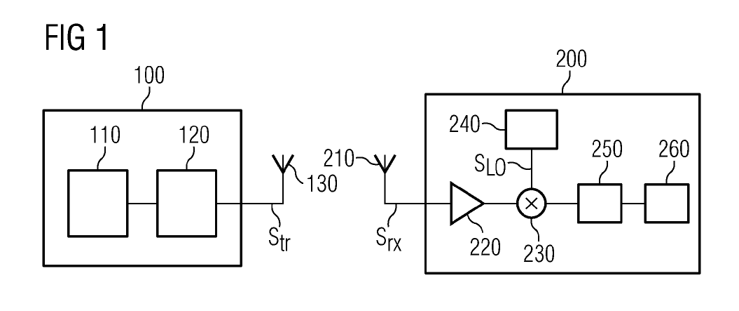

FIG. 1 shows a mobile transmit unit 100 and a receiver 200, according to an example embodiment. In addition to an antenna 130, the transmit unit 100 comprises a pulse generator 110, which generates a broadband transmit signal Sₜᵣ, for instance with a bandwidth Bₜᵣ≧500 MHz around an average frequency fₜᵣ of the oscillator 120, for instance fₜᵣ=7.25 GHz with the aid of a coherently oscillating oscillator 120. The frequency spectrum thus consists of lines with a fixed phase relationship at intervals from the pulse repetition rate fᵣₑₚ.

The shape and the oscillation frequency fₜᵣ of the output signal of the oscillator 120 determine the shape and position of the envelopes of the transmit signal Sₜᵣ in the spectrum. The frequency lines develop due to the coherent and periodic activation of the oscillator 120. In this way the frequency lines are at the frequencies which correspond to a multiple of the periodic pulse repetition rate.

The transmit signal Sₜᵣ includes several pulses, whereby two consecutive pulses comprise a temporal distance 1/fᵣₑₚ. Each pulse may be a cosine function overlayed and/or multiplied with a rectangular signal. The transmit signal Sₜᵣ can then be written as

$${S}_{tr} ( t ) = p ( t ) * {\sum }_{k} δ ( t - \frac{k}{{f}_{rep}} ) , wobeip ( t ) = rect ( t - {T}_{puls} ) \cdot cos ( {ω}_{0} t )$$

“δ” is the Dirac function and “rect(t−Tₚᵤₗₛ)” symbolizes the rectangular function, whereby Tₚᵤₗₛ specifies the time interval for which the pulse is to be sent. Furthermore, ω₀=2πfₜᵣ applies.

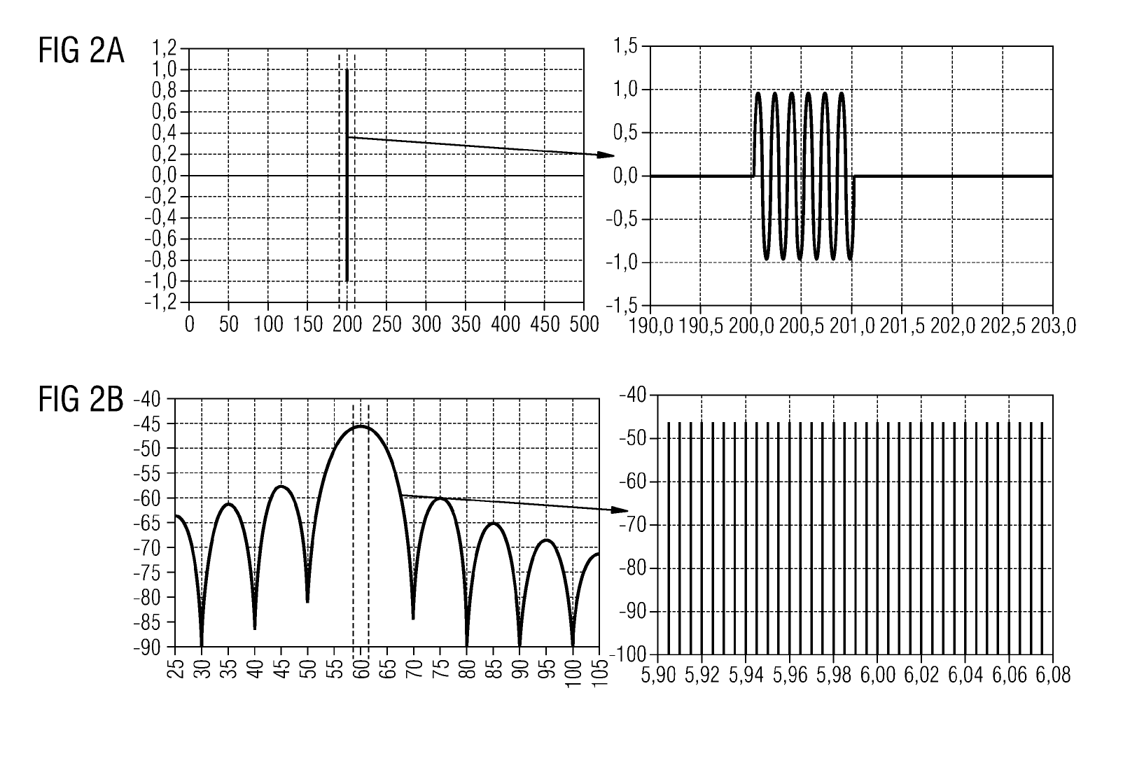

FIG. 2A shows the temporal curve of the pulsed transmit signal Sₜᵣ sent by the transmit unit 100, whereas FIG. 2B shows the spectrum of the transmit signal Sₜᵣ. Here the extract marked in the corresponding left-hand diagram is shown enlarged in the right-hand diagram in FIGS. 2A, 2B.

In order to determine the distance between the transmitter 100 and the receiver 200, use is made of the fact that the channel impulse response h(t) (and/or its Fourier transformed, the transfer and/or also transmission function H(ω)), which can be reconstructed from the received signal Sᵣₓ, depends on the delay τ of the signal. As is known, the connection SPEKᵣₓ(ω)=H(ω)·SPEKₜᵣ(ω) exists in the frequency space between the spectrum SPEKₜᵣ of the transmitted signal Sₜᵣ and the spectrum SPEKᵣₓ of the received signal Sᵣₓ. As is readily apparent, Hₘ(ω) can be described for a specific channel m (i.e. for a frequency line fₜᵣ(m)=m·fᵣₑₚ of the spectrum SPEKₜᵣ with m=0, 1, 2, . . . ) with Hₘ(ω)=cₘ·exp(−j·2π·m·fᵣₑₚ·τ), wherein τ corresponds to the delay of the transmitted signal from the transmitter 100 to the receiver 200, cₘ is a (complex) coefficient and fᵣₑₚ is the pulse repetition rate of the transmitted signal as mentioned above.

A Fourier transformation, in particular a discrete Fourier transformation (DFT), the transfer function Hₘ(ω) and/or the coefficient cₘ of the transfer function supplies the channel impulse response hₙ (t) in the temporal domain, from which the delay τ is ultimately determined:

hₙ(t)=DFT{Hₘ(ω)}=cₙ·δ(n/fᵣₑₚ−τ)

The receiver 200 (FIG. 1) comprises an antenna 210 for receiving the signal Sₜᵣ transmitted by the transmitter 100. The received time signal Sᵣₓ is likewise pulsed according to the transmitted time signal Sₜᵣ. Nevertheless, the received signal comprises a phase shift cₘ·exp(−j·2π·m·fᵣₑₚ·τ) for each frequency line m of the spectrum of Sᵣₓ compared with the phase of the corresponding frequency line of the spectrum of Sₜᵣ, whereby τ corresponds to the delay of a transmitted signal from the transmitter 100 to the receiver 200 and whereby cₘ is the complex coefficient introduced above.

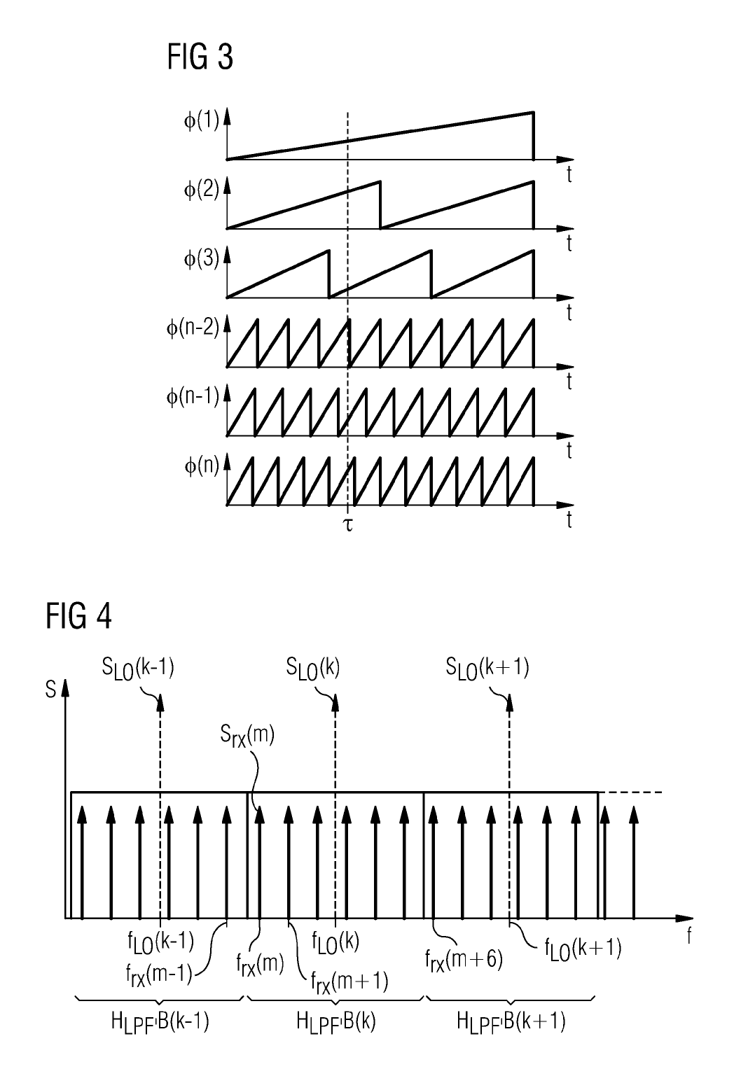

This is shown in FIG. 3 for different frequencies f(m) with m=1, 2, 3, . . . , w−2, w−1, whereby it is assumed that the spectrum of the transmit signal comprises a number w of different lines. At time instant τ, which corresponds to the delay, the different lines m of the spectrum comprise different phases Φ(m) in the receiver. Here the delay τ is however contained in the phase of each individual line. On account of the periodicity and the narrow uniqueness range associated therewith, the delay cannot be clearly reproduced from the phase information of an individual line. It is however possible to conclude the delay τ from the phase shifts for several different lines m of the spectrum of the receive signal. The aim is therefore to determine the coefficient cₘ for the individual lines m of the spectrum SPEKᵣₓ of the receive signal Sᵣₓ (both phase and also amplitude).

To this end, the received signal Sᵣₓ is initially amplified in an amplifier 220, resulting in an amplified signal Sᵣₓ′. The further signal processing would alternatively in principle be possible, including

a) the determination of the channel impulse response with the aid of the lines m of the spectrum SPEKᵣₓ and
b) the determination of the delay τ from the channel impulse response.

It is however advantageous for the received and if necessary amplified signal to initially be mixed down to a base band, to subsequently select a narrow band frequency range from the base band with the aid of a filter, said frequency range only containing a specific number of lines, and subsequently to implement the signal processing with a) and b) with the aid of these lines. On account of the thus lower data quantity to be processed, correspondingly lower demands are placed on the hardware.

This method takes place in several partial steps k, wherein a different narrow band frequency range B(k) is selected in each partial step k. B(k) therefore corresponds to a narrow band partial spectrum TSPEKᵣₓ of the spectrum SPEKᵣₓ, which covers a frequency range B having a narrower band width H_{LPR} and having a lesser number of lines m′ than the complete spectrum SPEKᵣₓ.

For transfer into the base band, the amplified signal Sᵣₓ′ is mixed down in a mixer 230 with an oscillator signal S_{LO} of the LO frequency f_{LO}(k) generated locally in a local oscillator 240 and is thus scanned in real form. The signal which can be taken from the mixer 230 is initially filtered in a filter 250, as a result of which a narrow band frequency range B(k) is filtered out of the base band signal and is then fed to an analog/digital converter (A/D converter) 260 for further processing. The filter 250 comprises a bandwidth H_{LPR}, for instance the filter can be designed as a rectangular low pass filter. The receiver 200 is likewise embodied in a broadband fashion in accordance with the bandwidth Bₜᵣ of the transmit signal Sₜᵣ.

The frequency f_{LO} of the local oscillator signal S_{LO} of the receiver 200 can be adjusted. This is used in the inventive method in order to adjust the frequency f_{LO}, as with a FSCW radar system in stages k with k=0, 1, 2, . . . above the overall UWB receive band, whereby the difference Δf_{LO}=f_{LO}(k)−f_{LO}(k−1) between two consecutive partial steps k−1, k remains constant. In this way the UWB receive band is identical to the UWB transmit band of the transmitter 100.

In a partial step k, a signal S_{LO}(k) is generated with the frequency f_{LO}(k), whereby this signal is generated in an in-phase manner with respect to the phase of the preceding signal S_{LO}(k−1). I.e. the relative phase of the LO signal S_{LO}(k) is known at each time instant and at each frequency stage k (i.e. the phase relationship between two signals S_{LO}(k), S_{LO}(k+1) is known). For illustration purposes, FIG. 4 shows a diagram, in which both the frequencies f_{LO}(k) of the receiver oscillator 240 are shown and also the spectrum of the receive signal Sᵣₓ having lines m at frequencies fᵣₓ(m) and (indicated) the resulting narrow band frequency ranges B(k). For clarity's sake, only a few lines fᵣₓ(m−1), fᵣₓ(m), fᵣₓ(m+1) are indicated.

Adjacent frequencies such as for instance f(k−1), f(k), f(k+1) and the bandwidth of the filter 250 can be attuned to one another such that the corresponding frequency ranges B(k−1), B(k), B(k+1), which each cover a bandwidth H_{LPR} in each instance, overlap at the edges. Alternatively, the tuning may also be such that no overlapping of adjacent frequency ranges B takes place.

The advanced signal processing in the A/D converter 260 contains at least the afore-described steps a) and b), whereby the channel impulse response hₖ is determined in a known manner in each partial step k with the aid of the lines disposed in the frequency range B(k) and the delay τ is determined from the channel impulse response hₖ. The coefficients c are initially determined in order to determine the channel impulse response, followed by a Fourier transformation.

The approach proposed here of measuring the distance between the transmitter 100 and the receiver 200 is based on a successive scanning of the spectrum SPEKᵣₓ of the receive signal Sᵣₓ, whereby a narrow band frequency range B(k) predetermined by the filter 250 in each instance is processed with a bandwidth H_{LPR} of the line spectrum of the receive signal Sᵣₓ with each partial step k and thus with each frequency f_{LO}(k). Individual pulses are no longer evaluated, but the complex signal of the respective frequency line is instead.

The line spectrum (FIG. 2B) produced by pulsing the transmitter 100 is successively, virtually coherently converted in the receiver 200 into a narrow band base band signal with the aid of the mixer 230. By analyzing the frequency lines in this narrow band signal, the frequency lines can be easily detected with the A/D converter 260 with a moderate scanning rate in the MHz range. The base band width should advantageously correspond here to at least the frequency line distances Δf_{LO}.

A known phase relationship between the oscillator 240 and the A/D converter 260 is important here. For further signal processing, the output signal of the filter 250 is transferred into the digital plane in the A/D converter 260. The scanning time instants used with the A/D conversion similarly determine the phase relationship to the signal.

The temporal information is obtained from the phase relationship between the frequency lines recorded one after the other respectively. Here the fact that a phase difference ΔΦ=2π*Δf*τ forms between two adjacent frequency lines of the received spectrum on account of the delay τ is beneficial.

Since the absolute starting time instant is not known, the delay differences are finally evaluated in a TDoA (time difference of arrival) approach.

The method for distance measurement can be summarized as follows:
The UWB transmitter 100 emits a pulsed time signal Sₜᵣ. The corresponding spectrum of the pulsed signal comprises lines, the distance of which from one another corresponds to the pulse repetition rate.
The receiver 200 does not process the complete signal in the spectrum per time step Δt but instead only individual lines therefrom. These are combined successively by the LO frequency f_{LO}(k) of the receiving oscillator being interconnected in stages k (one stage k per time step Δt) until the entire transmit spectrum is acquired.
The channel impulse response is also contained in the receiving spectrum. This is combined successively.
The channel impulse response provides information about the delay τ of the signals from the transmitter 100 to the receiver 200 and/or about the distance d therebetween.

A multidimensional position p can be determined for instance with the aid of the so-called “TDoA” method (time difference of arrival) via the time differences relating to various receivers. Assuming that several receivers and/or base stations are present, a multichannel system in the base stations can provide the time difference between the incident channels. The delay difference between several channels of the receiver is evaluated. Information is thus obtained which can be evaluated with the known TDoA method.

Alternatively, synchronous base stations and/or receivers can “simultaneously” execute a measurement in each instance. This method is similar to that afore-described, nevertheless the stations are synchronized to one another here, for instance by way of a suitable radio interface.

Alternatively, a TDoA measurement is also possible by way of a reference transmitter, whereby an additional UWB transmitter functions as a reference. A distinction can be made between the reference transmitter and the mobile transmitter by means of a different pulse repetition frequency and/or by means of a suitable modulation. In addition, only a rough synchronization is needed with several base stations on account of the minimal frequency difference between the transmitters.

The quality, for instance the signal-to-noise ratio and the phase noise of the base band signal is significantly dependent on the quality of the oscillators used in the transmitter and in the receiver. In order to compensate for a possible phase drift, the filter bandwidth of the ZF and base band filter 250 and the distance between two LO frequencies f_{LO}(k), f_{LO}(k+1) can be selected such that at least one line of the receive signal is present in the two base band signals.

In order to determine the precise frequency offset of the oscillators in the transmitter 100 and receiver 200, the receive signal Sᵣₓ can be recorded at a constant frequency f_{LO} over a longer time Δt and the frequencies thereof can be determined precisely. The longer observation duration increases the processing gain and as a result increases the signal-to-noise ratio.

What is claimed is:

1. A method for determining a delay τ of a signal between a UWB transmit unit and a FSCW receiver unit, comprising:
in a first step, generating a pulsed transmit signal Sₜᵣ by the transmit unit and emitting the pulsed transmit signal Sₜᵣ, the transmit signal Sₜᵣ comprising a broadband spectrum SPEKₜᵣ having a plurality of lines w;
in a second step, receiving the emitted signal Sₜᵣ by the receiver unit as a received signal Sᵣₓ, wherein the received signal Sᵣₓ comprises a broadband spectrum SPEKᵣₓ having a plurality of lines m;
in a third step, determining at the receiver unit a channel impulse response hₙ of the received signal Sᵣₓ;
in a fourth step, determining the signal delay τ based on the channel impulse response hₙ.

2. The method of claim 1, comprising:
after the second step, selecting from the broadband spectrum SPEKᵣₓ of the received signal Sᵣₓ a partial spectrum TSPEKᵣₓ that covers a frequency range B having a narrower bandwidth H_{LPR} and having a lesser number of lines m′;
in the third step, determining the channel impulse response h_{m′} using the lines m′ of the selected partial spectrums TSPEKᵣₓ; and
in the fourth step, determining the signal delay τ the channel impulse response h_{m′}.

3. The method of claim 1, wherein the method is executed in several partial steps k with k=1, 2, 3, . . . , the method comprising:
after the second step, selecting from the broadband spectrum SPEKᵣₓ of the received signal Sᵣₓ a partial spectrum TSPEKᵣₓ(k) that covers a frequency range B(k) having a narrower bandwidth H_{LPR} and having a lesser number of lines m′, wherein in each partial step k, another narrow band partial spectrum TSPEKᵣₓ(k) is selected,
in the third step, determining the channel impulse response h_{m′}(k) using the lines m′ of the selected partial spectrum TSPEKᵣₓ(k); and
in the fourth step, determining the signal delay τ from the channel impulse response h_{m′}(k).

4. The method of claim 3, wherein in a partial step k for selecting a partial spectrum TSPEKᵣₓ(k), a reference signal S_{LO}(k) is generated with a frequency f_{LO}(k),
wherein the received signal Sᵣₓ is mixed down with the LO signal S_{LO}(k) in a mixer; and
wherein the narrow band frequency range B(k) is selected from the output signal of the mixer which results therefrom.

5. The method of claim 4, wherein the frequency f_{LO}=f_{LO}(k) of the reference signal S_{LO}(k) is gradually changed for the individual partial steps k.

6. A distance measuring arrangement for measuring a signal delay τ between a transmit unit and a receiver unit,
wherein the transmit unit comprises an ultra wideband transmitter configured to transmit a pulsed transmit signal Sₜᵣ, wherein the transmit signal Sₜᵣ comprises a broadband spectrum SPEKₜᵣ having a plurality of lines w; and
the receiver unit comprises:
a FSCW receiver for receiving the transmitted transmit signal Sₜᵣ as a received signal Sᵣₓ, wherein the received signal Sᵣₓ includes a broadband spectrum SPEKᵣₓ having a plurality of lines m; and
an evaluation unit configured to determine a channel impulse response hₙ τ based on the received signal Sᵣₓ and to determine the signal delay τ based on the channel impulse response hₙ.

7. The distance measuring arrangement of claim 6, wherein the receiver unit further comprises:
an adjustable local oscillator for generating a local oscillator signal S_{LO}(k), wherein the signal S_{LO}(k) comprises a frequency f_{LO}(k) which can be adjusted in steps k with k=1, 2, . . . , and
a mixer, to which the received signal Sᵣₓ and the LO signal S_{LO}(k) can be fed and in which these signals are mixed in a base band signal,
wherein the output signal of the mixer is used to determine the channel impulse response hₙ and the signal delay τ in the evaluation unit.

8. The distance measuring arrangement of 7, wherein the receiver unit further comprises a filter, to which the base band signal is fed, and in which a narrow band partial spectrum TSPEKᵣₓ(k) can be selected from the spectrum of the base band signal, whereby instead of the output signal of the mixer, the output signal of the filter is used to determine the channel impulse response hₙ and the signal delay τ in the evaluation unit.

9. The distance measuring arrangement of claim 6, wherein:
the receiver unit is configured to select from the broadband spectrum SPEKᵣₓ of the received signal Sᵣₓ a partial spectrum TSPEKᵣₓ that covers a frequency range B having a narrower bandwidth H_{LPR} and having a lesser number of lines m′; and
the evaluation unit is configured to determine the channel impulse response h_{m′} using the lines m′ of the selected partial spectrums TSPEKᵣₓ, and to determine the signal delay τ the channel impulse response h_{m′}.

10. The distance measuring arrangement of claim 6, wherein:
the method is executed in several partial steps k with k=1, 2, 3, . . . ,
the receiver unit is configured to select from the broadband spectrum SPEKᵣₓ of the received signal Sᵣₓ a partial spectrum TSPEKᵣₓ(k) that covers a frequency range B(k) having a narrower bandwidth H_{LPR} and having a lesser number of lines m′, wherein in each partial step k, another narrow band partial spectrum TSPEKᵣₓ(k) is selected; and
the evaluation unit is configured to determine the channel impulse response h_{m′}(k) using the lines m′ of the selected partial spectrum TSPEKᵣₓ(k), and to determine the signal delay τ from the channel impulse response h_{m′}(k).

11. The distance measuring arrangement of claim 10, wherein:
in a partial step k for selecting a partial spectrum TSPEKᵣₓ(k), a reference signal S_{LO}(k) is generated with a frequency f_{LO}(k),
the received signal Sᵣₓ is mixed down with the LO signal S_{LO}(k) in a mixer; and
the narrow band frequency range B(k) is selected from the output signal of the mixer which results therefrom.

12. The distance measuring arrangement of claim 12, wherein the frequency f_{LO}=f_{LO}(k) of the reference signal S_{LO}(k) is gradually changed for the individual partial steps k.
